(19) United States
(12) Patent Application Publication
(10) Pub. No.: US 2014/0284806 A1
(43) Pub. Date: Sep. 25, 2014

(54) SEMICONDUCTOR DEVICE DIE ATTACHMENT

(71) Applicants: Junhua Luo, Tianjin (CN); Nan Xu, Tianjin (CN); Jinzhong Yao, Tianjin (CN)

(72) Inventors: Junhua Luo, Tianjin (CN); Nan Xu, Tianjin (CN); Jinzhong Yao, Tianjin (CN)

(21) Appl. No.: 14/183,511

(22) Filed: Feb. 18, 2014

(30) Foreign Application Priority Data
Mar. 19, 2013 (CN) 201310272492.5

(51) Int. Cl. H01L 23/48; H01L 25/00

(52) U.S. Cl. CPC H01L 23/48; H01L 25/50
USPC 257/773; 438/121

(57) ABSTRACT

A semiconductor device has first and semiconductor dies having active faces presenting electrical contact elements and back faces attached to first and second bonding areas side by side on an electrically conductive die support. A layer of electrically insulating material is applied to the first bonding area of the die support. A layer of electrically insulating adhesive bonding material attaches the back face of the first semiconductor die to the first bonding area of the die support through the layer of electrically insulating material. A layer of electrically conductive adhesive bonding material attaches the back face of the second semiconductor die to the second bonding area of the die support.

### BACKGROUND OF THE INVENTION

The present invention is directed to semiconductor device assembly and, more particularly, to a method of attaching a semiconductor die to a die support area of a substrate or lead frame.

Semiconductor devices are commonly packaged with a semiconductor die mounted on a die support with a back side of the die being attached to the die support and an active side of the die having contact pads facing up (or exposed). The die support may be a substrate or a flag (or paddle) of a lead frame, for example. During a typical die attach process, a liquid, viscous or malleable adhesive bonding material is disposed between the die and the support and allowed to solidify. Typical die bonding materials are polymer elastomeric adhesives such as epoxy resin which are cured to solidify; alternatively, soft solder or eutectic alloy may be placed between the die and the support, melted and then allowed to solidify.

If the die support is an electrically insulating substrate, then typically it also is thermally insulating. However, for certain types of semiconductor devices, it is desirable to mount the semiconductor die on a heat sink element, such as a metal or other thermally conductive flag, in order to distribute and dissipate internally generated heat. It also may be desired to electrically connect the back face of the semiconductor die with an electrically conductive die support, for example if the die support provides a voltage supply connection. On the other hand, it sometimes is desirable for the back face of the semiconductor die to be electrically insulated from an electrically and thermally conductive die support.

The semiconductor device may have a single semiconductor die, a stack of semiconductor dies, or dies placed side by side. It may be desired that the back face of one of the semiconductor dies be connected electrically with an electrically conductive die support, while the back face of another of the semiconductor dies is attached to but electrically insulated from the common electrically conductive die support.

In order to insulate the back face of a semiconductor die from an electrically conductive die support, an electrically insulating bonding material typically is utilized. However, it has been found that some failures occur due to unwanted electrical connection through the electrically insulating bonding material, for example due to conductive foreign material such as metal particles, or chipping or irregularities on the back face of the die. Increasing the thickness of the electrically insulating bonding material might reduce the incidence of failures but is insufficient to eliminate the failures without impractical or costly complication of the bonding process and increase undesirably the thermal insulation from the die support.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. In particular certain vertical dimensions may have been exaggerated relative to horizontal dimensions, for graphic reasons.

FIG. 1 is an enlarged cross-sectional view of a conventional semiconductor device having a semiconductor die attached to a die support;

FIG. 2 is a greatly enlarged cross-sectional view of a portion of the semiconductor die of FIG. 1;

FIG. 3 is an enlarged cross-sectional view of a conventional semiconductor device having two semiconductor dies attached to a common die support;

FIG. 4 is an enlarged cross-sectional view of a semiconductor device having a semiconductor die attached to a die support in accordance with one embodiment of the invention;

FIG. 5 is an enlarged cross-sectional view of a semiconductor device having two semiconductor dies attached to a common die support, one using insulating adhesive and the other using conductive adhesive, in accordance with another embodiment of the invention; and

FIG. 6 is a flow chart of a method of assembling a semiconductor device of the kind shown in FIG. 4 or 5 having a semiconductor die attached to a die support, or two semiconductor dies attached to a common die support, in accordance with an embodiment of the invention.

### DETAILED DESCRIPTION OF THE INVENTION

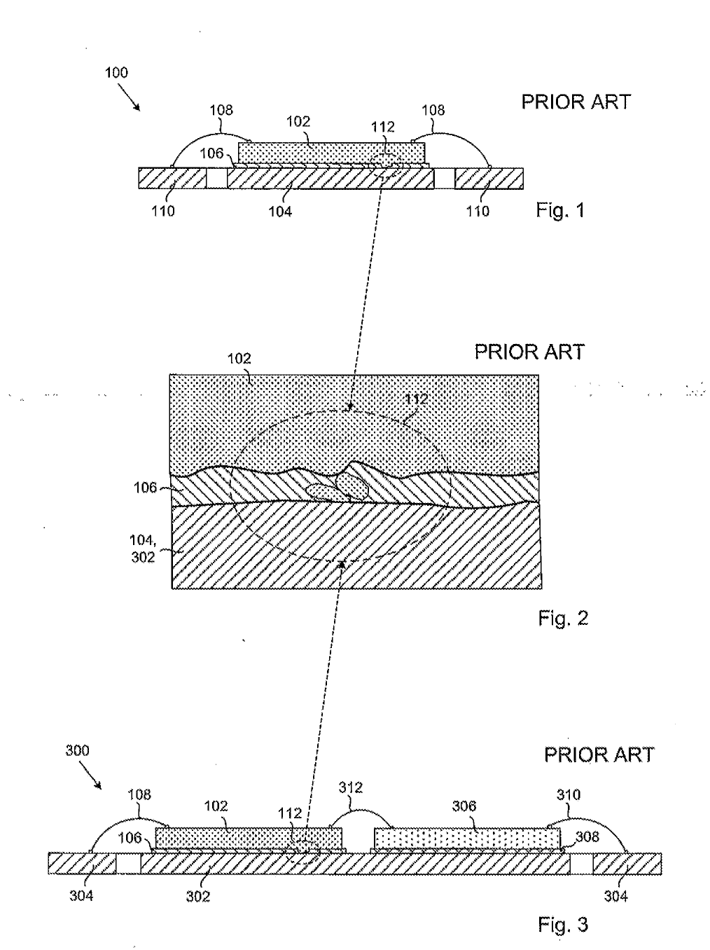

FIG. 1 illustrates a conventional semiconductor device 100 that has a semiconductor die 102 whose back face is attached to a die support 104 of a lead frame with a layer 106 of adhesive bonding material. The die support 104 is an electrically and thermally conductive flag, of copper alloy or another metal in this example and serves as a heat sink. The device 100 also has bond wires 108 that electrically connected contact pads (not shown) on the active face of the die 102 and lead fingers 110 on the lead frame providing external connections to the semiconductor device 100. The finished semiconductor device 100 is packaged, for example by encapsulation (not shown).

When it is desired to insulate the back face of the semiconductor die 102 from the die support 104, as in this example, an electrically insulating adhesive bonding material is chosen for the layer 106, for example a polymer elastomeric adhesive such as epoxy resin. The adhesive bonding material is applied in a flowable state such as a liquid, viscous or malleable paste state to the bonding area of the die support 104 or to the back face of the semiconductor die 102. The die 102 is then positioned on the lead frame before the bonding material is cured, which solidifies the bonding material.

FIG. 3 illustrates another conventional semiconductor device 300 that has a first semiconductor die 102 whose back face is attached to a die support 302 of a lead frame with a layer 106 of electrically insulating adhesive bonding material. The die support 104 is again an electrically and thermally conductive flag, of copper alloy or another metal in this example and serves as a heat sink. The device 300 also has bond wires 108 that electrically connect contact pads (not shown) on the active face of the first die 102 and lead fingers 304 of the lead frame providing external connections to the semiconductor device 300. The device 300 also has a second semiconductor die 306, positioned beside the first semiconductor die 102 and whose back face is attached to the die support 302 with a layer 308 of electrically conductive adhesive bonding material. The electrically conductive adhesive bonding material may be a soft solder or eutectic alloy, for example. The second semiconductor die 306 has bond wires 310 that electrically connect contact pads (not shown) on the active face of the second die 306 and other ones of the lead fingers 304, and may also have bond wire connections 312 between contact pads (not shown) on the active faces of the first and second dies 102 and 306.

The layer 308 may be placed between the second die 306 and the die support 302, melted and then allowed to solidify. The finished semiconductor device 300 is packaged, for example by encapsulation (not shown). The electrically conductive layer 308 ensures that the substrate of the second semiconductor die 306 is maintained at the voltage of the common die support 302 in use of the semiconductor device 300. It may be desired to maintain the substrate of the first semiconductor die 102 at a different voltage in use, which again requires the back face of the first semiconductor die 102 to be insulated electrically from the common die support 302.

The layer 106 of adhesive bonding material is kept thin. If the layer 106 is too thick, it increases the thermal insulation between the first semiconductor die 102 and the heat sink of the die support 104/302. Moreover, the thicker the layer 106, the more difficult it becomes to control the layer during fabrication. However, it has been found that the fabrication process of the semiconductor die 102 leads to some occurrences of conductive foreign material such as metal particles, or chipping or irregularities of the back face of the semiconductor material of the die, as shown at 112 in FIGS. 1 and 3, and at an enlarged scale in FIG. 2. Such occurrences can lead to failures due to unwanted electrical connection through the layer 106 of electrically insulating bonding material, caused by the conductive foreign material, or chipping or irregularities of the back face penetrating the electrically insulating bonding material when the die 102 is assembled on the bonding area of the lead frame while the layer 106 is still in a flowable state.

It would be possible in some cases to split the die support 302 into two parts that are insulated from each other. However, this would undesirably increase the package size. Moreover, in some cases it may still be desirable to insulate the first semiconductor die 102 from the part of the die support 302.

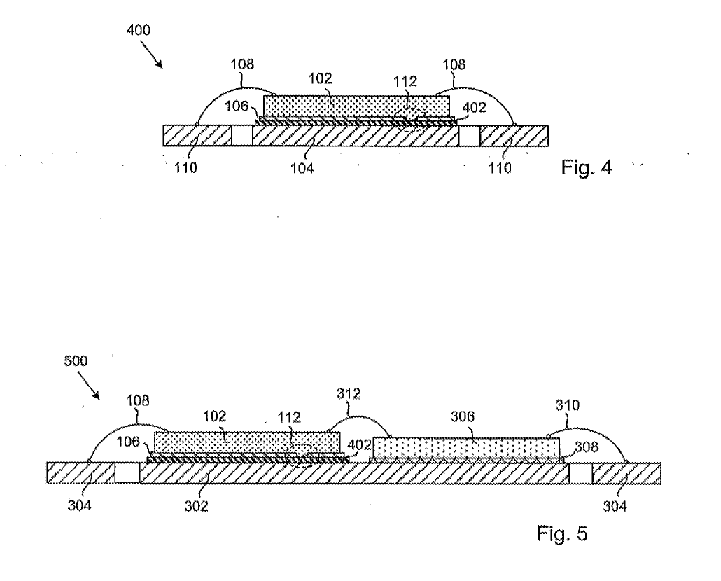

FIG. 4 illustrates a semiconductor device 400 in accordance with an embodiment of the invention, given by way of example. The semiconductor device 400 has a semiconductor die 102 having an active face presenting electrical contact elements and a back face opposite the active face. The semiconductor device 400 also has an electrically conductive die support 104 having a die bonding area. A layer of electrically insulating material 402 is applied to the bonding area of the die support 104 and a layer of electrically insulating adhesive bonding material 106 is used to attach the back face of the semiconductor die 102 to the bonding area of the die support 104 through the layer of electrically insulating material 402.

The layer of electrically insulating material 402 may be applied to the bonding area of the die support 104 with the layer of electrically insulating adhesive bonding material 106 to attach the back face of the semiconductor die 102 to the die support 104.

FIG. 5 illustrates a semiconductor device 500 in accordance with an embodiment of the invention, given by way of example. The semiconductor device 500 comprises first and second semiconductor dies 102 and 306 having respective active faces presenting electrical contact elements and respective back faces opposite the active faces. The semiconductor device 500 comprises an electrically conductive die support 302 having first and second side by side die bonding areas. A layer of electrically insulating material 402 is applied to the first bonding area of the die support 302 and a layer of electrically insulating adhesive die bonding material 106 is used to attach the back face of the first semiconductor die 102 to the first bonding area of the die support 302 through the layer of electrically insulating material 402. A layer of electrically conductive adhesive die bonding material 308 is used to attach the back face of the second semiconductor die 306 to the second bonding area of the die support 302.

The layer of electrically insulating material 402 may be applied to the first bonding area of the die support 302 and the layer of electrically insulating adhesive bonding material 106 attaches the back face of the first semiconductor die 102 to the layer of electrically insulating material 402. Thus, the device 500 if FIG. 5 is similar to the conventional device 300 shown in FIG. 3 except that the device 500 includes the layer 402 of electrically insulating material.

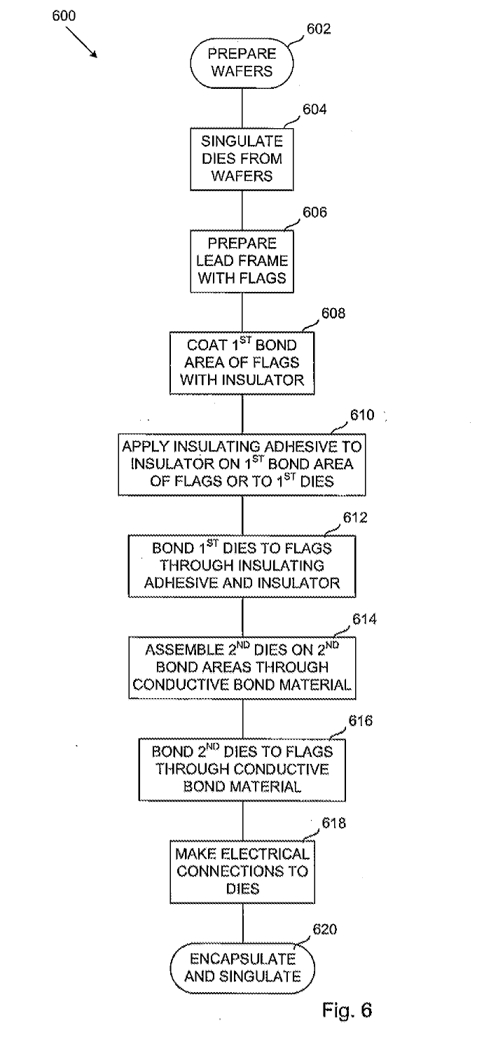

FIG. 6 illustrates a method 600 of making a semiconductor device in accordance with an embodiment of the invention, given by way of example. The method 600 is suitable for making a semiconductor device 400 or 500 of the kind shown in FIG. 4 or 5 having a semiconductor die attached to a die support, or having two semiconductor dies attached to a common die support. However the method 600 is also adaptable to making other semiconductor devices.

The method 600 comprises providing a semiconductor die 102 having an active face presenting electrical contact elements and a back face opposite the active face. An electrically conductive die support 104 or 302 having a bonding area is provided. A layer of electrically insulating material 402 is provided attached to the bonding area of the die support 104 or 302. A layer of electrically insulating adhesive bonding material 106 is provided attaching the back face of the semiconductor die 102 to the bonding area of the die support 104 or 302 through the layer of electrically insulating material 402.

Providing the layer of electrically insulating adhesive bonding material 106 may include providing the electrically insulating adhesive bonding material 106 in a flowable state on a surface of at least one of the layer of electrically insulating material 402 or, and the back face of said semiconductor die 102.

The layer of electrically insulating material 402 may be applied to the bonding area of the die support 104 or 302, and providing the layer of electrically insulating adhesive bonding material 106 may include providing the electrically insulating adhesive bonding material 106 in a flowable state on at least one of the back face of the semiconductor die 102 and the layer of electrically insulating material 402. The semiconductor die 102 and the bonding area of the die support 104 or 302 may be assembled together with the electrically insulating adhesive bonding material 106 and the layer of electrically insulating material 402 interposed, and the electrically insulating adhesive bonding material 106 transformed to an adhesive state.

The electrically conductive die support 302 may have a further bonding area disposed beside the first bonding area, and the method 600 may include providing a further semiconductor die 306 having an active face presenting electrical contact elements and a back face opposite the active face. A layer of electrically conductive adhesive bonding material 308 may be provided attaching the back face of the further semiconductor die 306 to the further bonding area of the die support 302.

The method 600 shown in FIG. 6 also illustrates the steps for assembling a semiconductor device 500 in accordance with an embodiment of the invention, given by way of example. The method 600 comprises providing first and second semiconductor dies 102 and 306 having respective active faces presenting electrical contact elements and respective back faces opposite the active faces. An electrically conductive die support 302 having first and second bonding areas side by side is provided. A layer of electrically insulating material 402 is provided applied to the first bonding area of the die support 302. A layer of electrically insulating adhesive bonding material 106 is provided attaching the back face of the first semiconductor die 102 to the first bonding area of the die support 302 through the layer of electrically insulating material 402. A layer of electrically conductive adhesive bonding material 308 is provided attaching the back face of the second semiconductor die 306 to the second bonding area of the die support 302.

Providing the layer of electrically insulating adhesive bonding material 106 may include providing the electrically insulating adhesive bonding material 106 in a flowable state on a surface of at least one of the layer of electrically insulating material 402, and the back face of said first semiconductor die 102.

The layer of electrically insulating material 402 may be applied to the first bonding area of the die support, and providing the layer of electrically insulating adhesive bonding material 106 may include providing the electrically insulating adhesive bonding material 106 in a flowable state on at least one of the back face of the first semiconductor die 102 and the layer of electrically insulating material 402. The first semiconductor die 102 and the first bonding area of the die support 302 may be assembled together with the electrically insulating adhesive bonding material 106 and the layer of electrically insulating material 402 interposed, and the electrically insulating adhesive bonding material 106 transformed to an adhesive state.

Providing a layer of electrically conductive adhesive bonding material 308 attaching the back face of the second semiconductor die 306 to the second bonding area of the die support 302 may include assembling together the second semiconductor die 306 and the second bonding area of the die support 302 with the electrically conductive adhesive bonding material 308 interposed, and transforming the electrically insulating adhesive bonding material to an adhesive state.

In more detail, in the example shown in FIG. 4, the semiconductor device 400 has a single semiconductor die 102 mounted on a die support 104. The die support 104 may be a substrate or ties of a lead frame for example. However in this example the die support is a flag (or paddle) of a lead frame forming a heat sink, the lead frame also having peripheral lands 110. The semiconductor die 102 may be made of any suitable semiconductor material such as silicon, for example, processed to fabricate an integrated circuit. The lead frame is made of a suitable electrically and thermally conductive material, such as copper alloy or another metal for example. The device 100 also has wire connections 108, of a suitable metal such as gold or aluminum for example, which connect the electrical contact pads (not shown) on the active face of the semiconductor die 102 and the peripheral lands 110, to which external electrical connections may be made in use. The semiconductor die 102 and the bonding wires 108 are encapsulated in the finished device 400, for example by molding material (not shown) applied over them and the mounting surface of the lead frame.

The back face of the semiconductor die 102 is attached to the die support 104 with a layer of electrically insulating material 402 and a layer of electrically insulating adhesive bonding material 106. The bonding material 106 may be, for example, a polymer elastomeric adhesive such as epoxy resin, while the insulating material 402 preferably is pre-applied to the lead frame (i.e., the die support 402) and may comprise any suitable insulating material such as an organic material, a resin, a silicone, a thick oxide like an oxidation layer having a thickness of between about 2 μm and 10 μm, a polymer, a ceramic, or a material such as silicon nitride, which also is used in wafer backside coating.

In the semiconductor device 400, the layer of electrically insulating material 402 first is applied to the bonding area of the die support 104, by a coating process such as deposition, plating or preferably screen printing, and then if necessary, cured to provide a continuous solid state layer that covers and adheres to the bonding area where the semiconductor die 102 is to be attached. The electrically insulating adhesive bonding material 106 is then provided in a flowable state on a surface of either or both of the layer of electrically insulating material 402 and the back face of the semiconductor die 102.

In one example of the semiconductor device 400, providing the electrically insulating adhesive bonding material 106 includes applying it to the relevant surface or surfaces in a flowable state such as a liquid, viscous or malleable paste state. The semiconductor die 102 and the bonding area of the die support 104 are then assembled together with the flowable electrically insulating adhesive bonding material 106 and the layer of electrically insulating material 402 interposed between them. The electrically insulating adhesive bonding material 106 is then transformed to an adhesive solid or elastomeric state by curing for example.

In another example of the semiconductor device 400, providing the electrically insulating adhesive bonding material 106 includes applying it in a solid state in contact with the relevant surface or surfaces. The semiconductor die 102 and the bonding area of the die support 104 are assembled together with the electrically insulating adhesive bonding material 106 and the layer of electrically insulating material 402 interposed between them. The electrically insulating adhesive bonding material 106 is then transformed to a flowable plastic or liquid state, by melting for example, and then transformed to an adhesive solid or elastomeric state, by solidification for example.

The semiconductor device 400 is illustrated with a single semiconductor die 102. It will be appreciated that the single semiconductor die 102 may be replaced by a stack of semiconductor dies that are connected together and/or to the lead frame (or substrate) internally and which have a single back face attached to the die support 104.

In the example shown in FIG. 5, the semiconductor device 500 is similar to the semiconductor device 400, except that the electrically conductive die support 102 with a single bonding area is replaced by the electrically conductive die support 302 of similar material. The semiconductor device 500 also has a further bonding area, disposed beside the first bonding area, on which is attached the back face of the further semiconductor die 306 by the layer of electrically conductive adhesive bonding material 308. The layer of electrically insulating adhesive bonding material 106 attaches the back face of the first semiconductor die 102 to the first bonding area of the die support 302 through the layer of electrically insulating material 402 and may be provided in the same way as in the semiconductor device 400. The layer of electrically insulating material 402 does not cover the further bonding area nor the back face of the further semiconductor die 306. The layer of electrically conductive adhesive bonding material 308 attaches the back face of the second semiconductor die 306 to the second bonding area of the die support 302 and provides an electrical connection between the back face of the second semiconductor die 306 and the die support 302.

In one example of the semiconductor device 500, providing the electrically conductive bonding material 308 includes applying it to the relevant surface or surfaces in a flowable state such as a liquid, viscous or malleable paste state. The further semiconductor die 306 and the further bonding area of the die support 302 are then assembled together with the flowable electrically conductive bonding material 308 interposed between them. The electrically conductive bonding material 106 is then transformed to an adhesive solid or elastomeric state by curing, for example, to attach and connect electrically together the further semiconductor die 306 and the die support 302.

In another example of the semiconductor device 500, providing the electrically conductive bonding material 308 includes assembling together the semiconductor die 102 and the bonding area of the die support 104 with the electrically conductive bonding material 308 in a solid state interposed in contact with the relevant surface or surfaces. The electrically conductive bonding material 308 is then transformed to a flowable plastic or liquid state, by melting for example, and then transformed to an adhesive solid or elastomeric state, by solidification for example, to attach and connect electrically together the further semiconductor die 306 and the die support 302. In one example, the electrically conductive bonding material 308 is a solder.

FIG. 6 illustrates steps in the method 600 of assembling semiconductor devices. The method is described with reference to making the semiconductor device 500, but it will be appreciated that the method can be adapted to making other semiconductor devices. Also, the method is described with reference to making semiconductor devices with two bonding areas side by side and at least two semiconductor dies 102 and 306 attached to the respective bonding areas but it can be adapted to making the semiconductor device 400 by omitting the steps relating to second semiconductor dies 306.

The method 600 begins at 602 by preparing and providing wafers having arrays of first and second semiconductor dies 102 and 306 fabricated in the wafers. At 604, the semiconductor dies 102 and 306 are singulated from the wafers. At 606, lead frames having die supports 302 in the form of thermally and electrically conductive flags are prepared and provided. At 608, the first bond areas on the die supports 302 are coated with the layer of electrical insulator 402. However, in a variant of the method, the first bond areas on the die supports 302 are coated with the layer of electrical insulator 402 when the lead frames are prepared at 606. At 610, the layer of electrically insulating adhesive bonding material 106 is applied in a flowable state to the first bonding areas of the die supports 302 or to the back faces of the first semiconductor dies 102. The first semiconductor dies 102 are assembled on the first bonding areas of the die supports 302 and the interposed layers of electrically insulating adhesive bonding material 106 are transformed to an adhesive state to attach the first semiconductor dies 102 to the die supports 302 through the layers of electrically insulating material 402, at 612.

At 614, the second semiconductor dies 306 are assembled on the second bonding areas of the die supports 302 with the layer of electrically conductive bonding material 308 interposed. At 616, the layer of electrically conductive bonding material 308 are transformed to an adhesive state to bond and connect electrically the second semiconductor dies 306 to the die supports 302. At 618, electrical connections are made between the contacts on the active faces of the first and second dies 102 and 306 and the lands 304 on the lead frame. At 620, the semiconductor devices 500 are encapsulated and singulated.

It will be appreciated that the order in which certain of the steps of the methods 600 are performed may be changed. For example, the steps of preparing the lead frames at 606 may precede the preparation and singulation of the wafers at 602. In addition the steps 614 and 616 of bonding the second semiconductor dies 306 to the die supports 302 may precede the steps of preparing and singulating the wafers with the first semiconductor dies 102 and bonding the first semiconductor dies 102 to the die supports 302 through the layers of electrically insulating material 402.

In the foregoing specification, the invention has been described with reference to specific examples of embodiments of the invention. It will, however, be evident that various modifications and changes may be made therein without departing from the broader spirit and scope of the invention as set forth in the appended claims.

For example, the semiconductor material of the dies 102 and 306 can be any semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

In the claims, the word ‘comprising’ or ‘having’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A semiconductor device, comprising:
a semiconductor die having an active face presenting electrical contact elements and a back face opposite said active face;
an electrically conductive die support having a first die bonding area;
a layer of electrically insulating material applied to said first die bonding area of said die support; and
a layer of electrically insulating adhesive die bonding material that attaches said back face of said semiconductor die to said first die bonding area of said die support through said layer of electrically insulating material.

2. The semiconductor device of claim 1, wherein said layer of electrically insulating material is applied to said first die bonding area of said die support and said layer of electrically insulating adhesive die bonding material attaches said back face of said semiconductor die to said layer of electrically insulating material.

3. The semiconductor device of claim 1, wherein said electrically conductive die support has a further die bonding area disposed beside said first die bonding area, and the semiconductor device includes a further semiconductor die having an active face presenting electrical contact elements and a back face opposite said active face, and a layer of electrically conductive adhesive bonding material attaching said back face of said further semiconductor die to said further die bonding area of said die support.

4. A semiconductor device, comprising:
first and second semiconductor dies having respective active faces presenting electrical contact elements and respective back faces opposite said active faces;
an electrically conductive die support having first and second side by side die bonding areas;
a layer of electrically insulating material applied to said first die bonding area of said die support;
a layer of electrically insulating adhesive die bonding material that attaches said back face of said first semiconductor die to said first die bonding area of said die support through said layer of electrically insulating material; and
a layer of electrically conductive adhesive die bonding material that attaches said back face of said second semiconductor die to said second die bonding area of said die support.

5. The semiconductor device of claim 4, wherein said layer of electrically insulating material is applied to said first die bonding area of said die support and said layer of electrically insulating adhesive die bonding material attaches said back face of said first semiconductor die to said layer of electrically insulating material.

6. A method of assembling a semiconductor device, comprising:
providing a semiconductor die having an active face presenting electrical contact elements and a back face opposite said active face;
providing an electrically conductive die support having a first die bonding area;
disposing a layer of electrically insulating material on said first die bonding area of said die support; and
attaching said back face of said semiconductor die to said first die bonding area of said die support with an electrically insulating adhesive die bonding material.

7. The method of claim 6, wherein disposing said layer of electrically insulating material comprises screen printing said electrically insulating material onto said first die bonding area before attaching said back face of said semiconductor die to said first die bonding area.

8. The method of claim 6, wherein attaching said back face of said semiconductor die with said electrically insulating adhesive die bonding material includes providing said electrically insulating adhesive die bonding material in a flowable state on a surface of at least one of said layer of electrically insulating material, and said back face of said semiconductor die.

9. The method of claim 6, wherein said layer of electrically insulating material is applied to said die bonding area of said die support, and attaching said semiconductor die includes providing said electrically insulating adhesive die bonding material in a flowable state on at least one of said back face of said semiconductor die and said layer of electrically insulating material, assembling together said semiconductor die and said die bonding area of said die support with said electrically insulating adhesive die bonding material and said layer of electrically insulating material interposed, and transforming said electrically insulating adhesive die bonding material to an adhesive state.

10. The method of claim 6, wherein said electrically conductive die support has a further die bonding area disposed beside said first die bonding area, and the method includes:
providing a further semiconductor die having an active face presenting electrical contact elements and a back face opposite said active face; and
attaching said back face of said further semiconductor die to said further die bonding area of said die support with an electrically conductive adhesive die bonding material.
